(19) United States
(12) Patent Application Publication
(10) Pub. No.: US 2026/0126486 A1
(43) Pub. Date: May 7, 2026

(54) MULTICAST-BASED TESTBENCH FOR DEVICE TESTING

(71) Applicant: Toyota Jidosha Kabushiki Kaisha, Toyota-shi Aichi-ken (JP)

(72) Inventors: Joshua Scott Smith, Livonia, MI (US); Sean S. Norris, Washington, DC (US)

(73) Assignee: Toyota Jidosha Kabushiki Kaisha, Toyota-shi Aichi-ken (JP)

(21) Appl. No.: 19/427,080

(22) Filed: Dec. 19, 2025

Related U.S. Application Data
(63) Continuation-in-part of application No. 18/771,089, filed on Jul. 12, 2024.

(51) Int. Cl. G01R 31/3183

(52) U.S. Cl. CPC G01R 31/318357

(57) ABSTRACT

Systems, methods, and other embodiments described herein relate to improving the testing of electronic devices using adaptable interfaces. In one embodiment, a method includes receiving a set of virtual electronic control units, receiving a set of interface devices connected to test devices, simulating wire harnesses where each wire harness contains a subset of virtual electronic control units and a subset of interface devices, both of which are configured to communicate therein based on a multicast protocol, and injecting a fault in a target wire harness affecting a test device connected to the subset of interface devices associated with the target wire harness in accordance with a multicast group assignment.

### CLAIM OF PRIORITY

The present application is a continuation-in-part application of U.S. patent application Ser. No. 18/771,089, entitled “ADAPTABLE HARDWARE INTERFACE FOR DEVICE TESTING”, which was filed on Jul. 12, 2024, and is incorporated herein by reference in its entirety.

### TECHNICAL FIELD

The subject matter described herein relates, in general, to testing electronic devices and, more particularly, to an adaptable interface that provides access to devices under test in a configurable manner through multicast-based test networks.

### BACKGROUND

Developers implement test benches to provide a controlled environment for developing software for new devices and testing that the new devices function as expected. In general, test benches are built on a per-device basis. As one example, in the context of vehicle electronic control units (ECUs), a test bench may include a custom wire harness that connects various different devices together while also providing additional connections for testing purposes. However, the uniqueness of these test benches requires institutional knowledge to effectively use them, thus limiting the ability for these benches to be shared between many developers and complicating access overall. Moreover, as the complexity of the device or arrangement of devices under test increases and/or testing requirements increase, the wiring harnesses also become more complex and difficult to build and maintain. Additionally, the increase in complexity also leads to increased costs for a test setup that is not reusable, thereby leading to further waste.

### SUMMARY

Example systems and methods relate to testing electronic devices using an adaptable interface. As previously noted, test benches can be complex to implement because of various considerations, including the complexity of the device or devices being tested. This leads to increased costs and waste since these test benches are complex to implement and not typically reusable. Therefore, in at least one approach, an inventive system is disclosed that provides an adaptable interface and associated logic to improve the testing of electronic devices. For example, in at least one aspect, an interface device is comprised of a controller, a memory, a bridge, and a connector for supporting communication with a device under test (i.e., an electronic device). The electronic device may take many different forms, including a module with multiple die packages, a single die package, and so on. As described herein, the electronic device is generally an electronic control unit as may be used within a vehicle. It should be appreciated that while the present disclosure focuses on the context of a vehicle, the disclosed devices, systems, and methods are applicable to other contexts.

In any case, consider that an electronic device, such as an ECU or multiple ECUs, is generally connected using a complex wiring harness when installed within a vehicle. The wiring harness may include a connector for each separate ECU with wiring therebetween. Moreover, within the context of testing, the wire harness may be further implemented to include diagnostic connectors for providing diagnostic signals. However, as noted previously, specifically designing a unique wiring harness for each different configuration of electronic devices that may need to be tested is complex. As such, the interface device resolves this issue by using the bridge to connect with multiple electronic devices under test, such as multiple different ECUs. The bridge connects to a respective electronic device via connector pins that may be separate pins of a device or arranged in a combined connector. The connector pins connect the bridge with an explicit connector port associated with the electronic device being tested (e.g., an ECU) or directly to pins of a die package or other electronic device (e.g., sensor).

Consequently, the connector pins may be specific to the particular electronic device, but this is in place of a more complex harness that cannot be modified to different arrangements. Because the connector pins from the bridge to the electronic device is unique in each instance, the interface further includes a memory, which may be an EEPROM or similar type of non-volatile memory, that stores configuration information about the electronic device and other devices under test that are connected via connector pins to the bridge. The contents of the configuration information may vary by implementation but generally includes descriptive data identifying the electronic device (e.g., serial number or other identifier, version number, etc.) and a mapping of the connector pins. The mapping identifies the correlation of the pins of the electronic device with ports of the bridge on which the pins are connected and exposed for communication. Accordingly, a controller mediates access to the electronic device by communicating the configuration information so that a test server or other test administering device can access the electronic device.

In various arrangements, the interface device communicates with an edge service and/or a cloud service, which function to simplify access to the device(s) under test. The edge service may aggregate configuration information from multiple different interface devices that connect with different electronic devices. Thus, the edge service may connect with the interface device via an ethernet switch or other communication network and functions to acquire the configuration information for a set of electronic devices associated with different interface devices. As a result, the edge service generates a mapping of the set of electronic devices and the associated connections provided via the respective bridges. A testing system can then use the edge service to form a virtual wire harness through the use of the mapping to emulate connections between the different electronic devices. That is, the edge service can provide for connecting the different electronic devices via the interface devices in a similar manner as would occur with a physical wire harness but without the complexity and waste of implementing the wire harness. Moreover, a cloud service may further aggregate mappings from multiple edge services. The cloud service can then provide access to remote clients in addition to permitting additional functionality, such as the provisioning of more complex virtual harnesses between separate edge services, reservations, data analytics, and so on, thereby improving access to the device(s). In this way, the disclosed approach is able to improve testing of electronic devices by avoiding complex, expensive, and potentially wasteful physical harnesses for testing.

In one embodiment, a system is disclosed. The system includes one or more processors and a memory communicably coupled to the one or more processors. The memory stores a control module that includes instructions that, when executed by the one or more processors, cause the one or more processors to

In one embodiment, a non-transitory computer-readable medium including instructions that, when executed by one or more processors, cause the one or more processors to perform one or more functions is disclosed. The instructions include instructions to

In one embodiment, a method is disclosed. In one embodiment, the method includes

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of an interface system that is associated with an adaptable platform for testing electronic devices.

FIG. 2A illustrates one embodiment of an interface device and connected devices.

FIG. 2B illustrates one embodiment of the interface device of FIG. 2A with additional details illustrated.

FIG. 3 illustrates a flowchart of communications between an interface device and a test service.

FIG. 4 is a flowchart representing a method associated with using an interface device to mediate communications with a device under test.

FIG. 5 illustrates one configuration of an edge service that includes multiple interface devices.

FIG. 6 illustrates one configuration of a cloud-based service that utilizes interface devices to provide emulation of physical wire harnesses.

FIG. 7 is a flowchart illustrating a method associated with emulating a wire harness.

FIG. 8 is a diagram illustrating one arrangement of a rack system that houses multiple networks of interface devices.

FIG. 9 illustrates one configuration of virtual wire harnesses that utilize multicast protocols.

FIG. 10 illustrates an example of connecting a DUT to wire harnesses using multicast.

FIG. 11 illustrates another example of connecting a DUT to wire harnesses using multicast.

FIG. 12 is a flowchart illustrating a method associated with fault injection in multicast-based wire harnesses.

### DETAILED DESCRIPTION

Systems, methods, and other embodiments associated with testing electronic devices using an adaptable interface are disclosed. As previously noted, test benches can be complex to implement because of various considerations, including the complexity of the device(s) being tested. This leads to increased costs and waste since these test benches are complex to implement and are unique to the particular instance, thereby not being reusable. By way of example, within the context of a vehicle, a wiring harness may connect with a dozen or more electronic control units. Each of the electronic control units (ECUs) undergoes development and testing to implement particular functionality in the vehicle in a manner that the developers desire. Thus, each different configuration of systems within a vehicle during development and each separate iteration of different ECUs that may be selected require a new wiring harness to be manually fabricated. Consequently, the ability to iterate designs when developing a new platform can be costly, thereby potentially limiting development.

Therefore, in at least one approach, an inventive system is disclosed that provides an adaptable interface and associated logic to improve the testing of electronic devices. For example, in at least one aspect, an interface device is comprised of a controller, a memory, a bridge, and a connector for supporting communication with a device under test (i.e., an electronic device, which is also referred to as a test device herein). The electronic device may take many different forms, including a module with multiple die packages, a single die package, a system on a chip (SoC), and so on. As described herein, the electronic device is generally an electronic control unit (ECU) as may be used within a vehicle. It should be appreciated that while the present disclosure focuses on the context of a vehicle, the disclosed devices, systems, and methods are applicable to other contexts and the discussed context should not be construed as limiting.

In any case, consider that an electronic device, such as an ECU or multiple ECUs are generally connected using a complex wiring harness when installed within a vehicle. The wiring harness may include a connector for each separate ECU with wiring therebetween. Moreover, within the context of testing, the wire harness may be further implemented to include diagnostic connectors for providing diagnostic signals. However, as noted previously, specifically designing a unique wiring harness for each different configuration of electronic devices that may need to be tested is complex. As such, the interface device resolves this issue by using the bridge to connect with multiple electronic devices under test, such as multiple different ECUs. The bridge connects to a respective electronic device via a connector pins. The connector pins connect the bridge with an explicit connector port associated with the electronic device being tested (e.g., an ECU) or directly to pins of a die package or other electronic device (e.g., sensor).

Consequently, the connector pins may be specific to the particular electronic device, but this is in place of a more complex harness that cannot be modified for different arrangements. Because the connector pins from the bridge to the electronic device is unique in each instance, the interface device further includes a memory, which may be an EEPROM or similar type of non-volatile memory, that stores configuration information about the electronic device and other devices under test that are connected via other connector pins to the bridge. The contents of the configuration information may vary by implementation but generally include descriptive data identifying the electronic device (e.g., serial number or other identifier, version number, etc.) and a mapping of the connector pins. The mapping identifies the correlation of the pins of the electronic device with the ports of the bridge on which the pins are connected and exposed for communication. Accordingly, a controller mediates access to the electronic device by communicating the configuration information so that a test server or other test administering device can access the electronic device via the bridge by using the mapping.

In various further arrangements, the interface device communicates with an edge service and/or a cloud service. The edge service may function over a network connection with the interface device to aggregate configuration information from multiple different interface devices that connect with different electronic devices. Thus, the edge service may connect with the interface device via an ethernet switch or communication network and functions to acquire the configuration information for a set of electronic devices associated with different interface devices. As a result, the edge service generates a mapping of the set of electronic devices and the associated connections provided via the respective bridges. A testing system can then use the edge service to form a virtual wire harness through the use of the mapping to emulate connections between the different electronic devices. That is, the edge service can provide for connecting the different electronic devices via the interface devices in a similar manner as would occur with a physical wire harness but without the complexity and waste of implementing the wire harness.

Moreover, a cloud service may further aggregate mappings from multiple edge services to provide additional functionality. The cloud service can provide access for remote clients in addition to permitting additional functionality, such as the provisioning of more complex virtual harnesses between separate edge services, reservations for scheduling testing among different entities, data analytics, and so on. In this way, the disclosed approach is able to improve testing of electronic devices by avoiding complex, expensive, and potentially wasteful physical harnesses for testing.

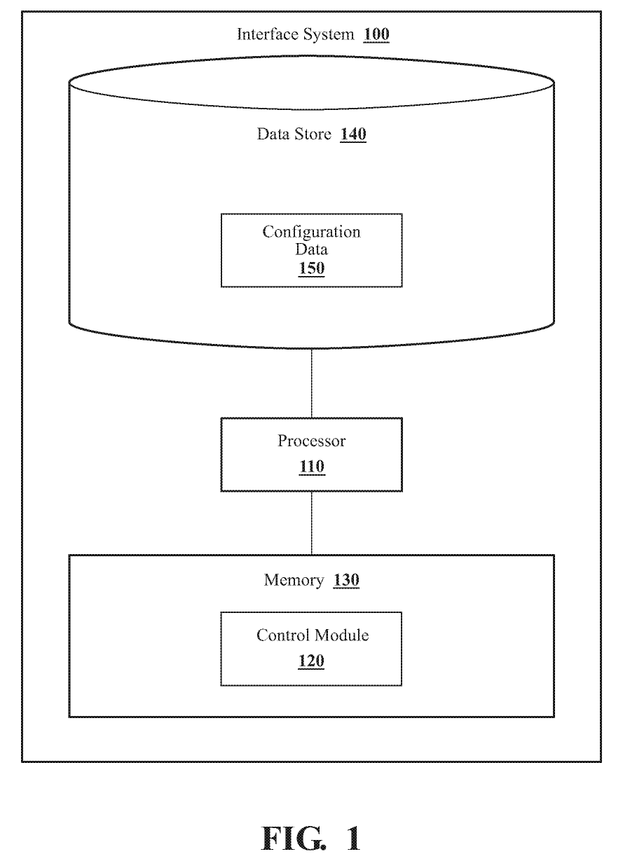

With reference to FIG. 1, one embodiment of an interface system 100 is illustrated. The interface system 100 is shown as including a processor 110, which may be integrated within the interface system 100 or may be associated with a separate computing device, such as a server, cloud-computing system, and so on. Accordingly, the processor 110 may be a part of the interface system 100, or the interface system 100 may access the processor 110 through a data bus or another communication path. In one embodiment, the interface system 100 includes a memory 130 that stores a control module 120. The memory 130 is a random-access memory (RAM), read-only memory (ROM), a hard-disk drive, a flash memory, or another suitable memory for storing the control module 120. The control module 120 is, for example, computer-readable instructions that, when executed by the processor 110, cause the processor 110 to perform the various functions disclosed herein. In alternative arrangements, the control module 120 is independent from the memory 130 and is, for example, comprised of hardware elements (e.g., arrangements of logic gates). Thus, the control module 120 is alternatively an ASIC, a hardware-based controller, a composition of logic gates, or another hardware-based solution.

The interface system 100, as illustrated in FIG. 1, is an abstracted form of the interface system 100 as may be implemented as part of an interface device, an edge service, and/or a cloud-computing system. It should be appreciated that the functionality discussed in relation to the interface system 100 may be wholly retained within a single device, such as the interface device itself, or may be distributed among multiple different devices, such as interface devices, computing elements functioning as edge services, computing elements functioning as cloud services, and so on. As such, the particular arrangement described in relation to FIG. 1 is not intended to be limiting but as an example of how the specific functions described herein may be executed in relation to a computing device.

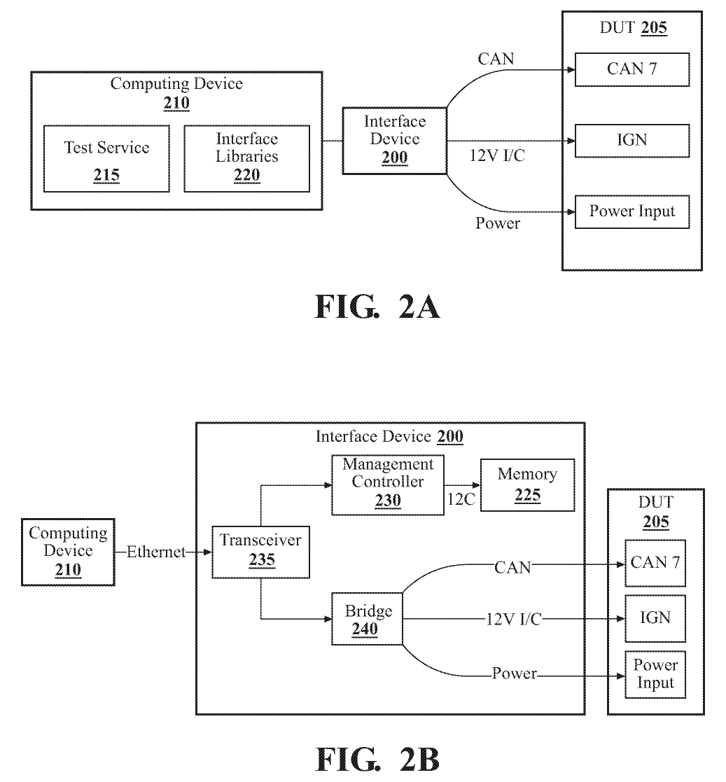

With reference to FIG. 2A, one example of an interface device 200 (also referred to as a hardware interface (HWI) herein) is illustrated. The interface device 200, as shown, connects with a device under test (DUT) 205. The DUT 205 may, in general, be any electronic device that is being tested, such as an ECU, or other electronic module. The interface device 200 connects with the DUT 205 via connector pins that is specific to the DUT 205. As illustrated in the present example, the connector pins include three primary connections that may be comprised of multiple separate wires each. In particular, the DUT 205 is connected via a control area connection (CAN), a 12 V I/O, and a power line. These separate portions of the connector pins interface with a CAN port, and IGN port, and a power input, respectively. Thus, as can be appreciated from the present example, the connector pins for each separate DUT may be unique to that DUT and is, therefore, implemented, in at least one arrangement, on a per-device basis. As an additional aspect, while the interface device 200 is shown in FIG. 2A as connecting with a single DUT 205, in various arrangements, the interface device 200 is capable of connecting multiple separate DUTs. The number of devices to which the interface device 200 connects is generally only limited by attributes of hardware included within the interface device 200 itself, such as a communication bridge that may have a certain number of ports within which to connect.

Separately, the interface device 200, in the illustrated example, connects with a computing device 210. The computing device 210 is, in one or more configurations, a server, a desktop computer, a laptop, or another device that is capable of executing instructions for testing the DUT 205 and communicating via the interface device 200. The computing device 210 executes a test service 215 that includes instructions for testing the DUT 205. For example, the test service 215 may include instructions to provide automated testing and/or a manual interface to the DUT for manual testing. The testing may take different forms depending on the particular use, but can include diagnostics testing, development of software for use on the DUT 205, debugging, and so on.

In any case, the test service 215 uses interface libraries 220 to provide for interfacing with the interface device 200 and the DUT 205. That is, the interface libraries 220 may form an application program interface (API) or other software library that provides functions for facilitating communications between the computing device 210 and the interface device 200 over an Ethernet connection or other electronic communication link. For further details of the interface device 200, consider FIG. 2B, which shows additional components of one example of the interface device 200 of FIG. 2A. As illustrated, the interface device 200 includes a memory 225, a management controller 230, a transceiver 235, and a bridge 240.

The transceiver 235 provides for communicating over an Ethernet connection or other communication link with the computing device 210 and may further route communications within the interface device 200 itself. For example, depending on the request provided by the computing device 210 via the interface libraries 220, the transceiver 235 may route the communication to the management controller 230 or directly to the bridge 240. The management controller 230 may be an ASIC, logic, or other programmable processing device that handles initialization requests from the computing device 210 or another external device. For example, the management controller 230 may receive an initialization request for information about one or more DUTs connected to the interface device 200. In general, the interface device 200 stores configuration information for each DUT that is connected with the interface device 200. The interface device 200 may store the configuration information in the memory 225. The memory 225 is, for example, an EEPROM, or other non-volatile memory.

The configuration information stored in the memory 225 includes information about the DUT 205 and the connector pins that connects the DUT 205 with the bridge 240. The information about the DUT 205 can include a device identifier, version number, and other attributes (e.g., device specifications, such as memory, processing capabilities, etc.). The connector pins information includes a mapping or listing of how the pins of the DUT 205 are connected with the bridge 240. Thus, the pin information correlates the pins to ports of the bridge 240 so that the requesting device (i.e., the computing device 210) can generate a mapping for subsequently powering, controlling, and otherwise communicating with the DUT 205. Accordingly, the test service 215 uses the interface libraries 220 to build a mapping that provides for routing signals generated by the test service 215 when executing a test program to the appropriate pins of the DUT 205. In general, the mapping defines ports associated with the bridge 240 for communicating signals on particular pins of the DUT 205. In this way, the interface device 200 exposes the DUT 205 for interactions with external devices.

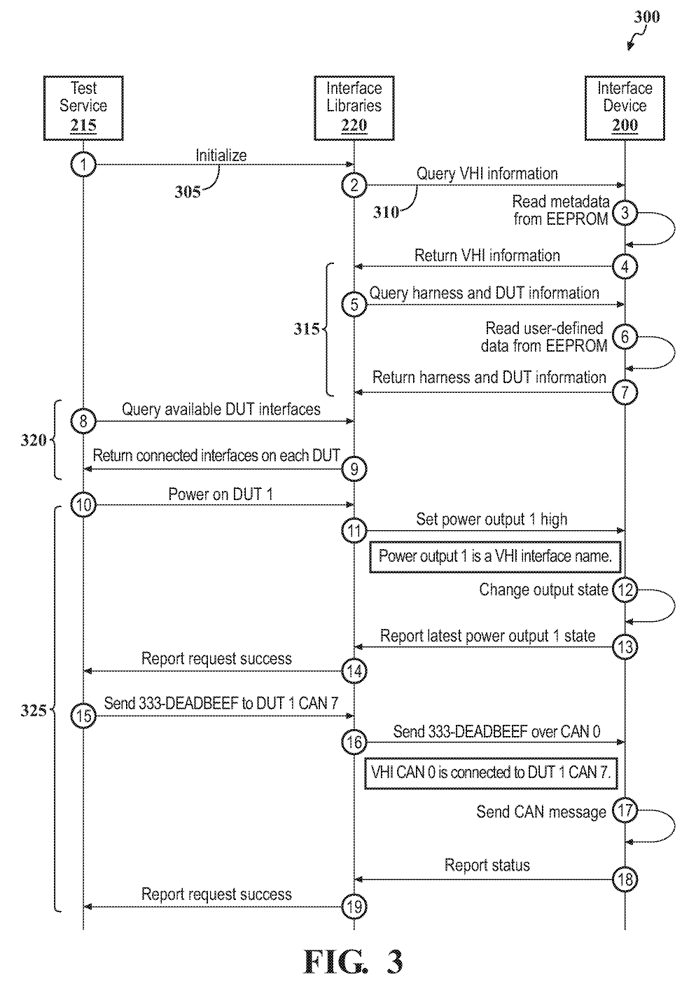

Continuing to FIG. 3, an example 300 of communications between the test service 215, the interface libraries 220, and the interface device 200 are represented. As additional context, the test service 215 is, in at least one arrangement, an automated testing program that provides a defined set of inputs to the DUT 205 while recording responses in order to characterize the performance of the DUT 205 (e.g., whether the DUT 205 is operating as expected). In further arrangements, the test service 215 may be a development environment for generating software code and loading the software code into the DUT 205 for execution. In still further arrangements, the test service 215 is a manual testing interface that allows a user to select inputs to provide directly to the DUT 205. In yet further arrangements, the test service 215 is a client for interfacing with external requests from remote applications. For example, the test service 215 may interface with an edge service, a cloud-based service, or another entity in order to provide access to the DUT 205 or other attached DUTs of the interface device 200.

In any case, the test service 215 initiates communication with the interface device 200 at 305. In order to provide the communication in the appropriate form, the interface libraries 220, which may be implemented as instructions executing as part of the test service 215, process the request into a query to the interface device, as shown at 310. Responsive to the query, the interface device 200 via the management controller 230 acts to retrieve the configuration information from the memory 225 and communicate the configuration information back to the interface libraries, which is shown as a multistep process at 315. While shown as being retrieved over multiple steps, in various arrangements, the interface device 200 may provide contents of the configuration information in a single communication or in multiple communications depending on, for example, buffer sizes and/or other hardware constraints.

The interface libraries 220 then function to generate the mapping of the pins of the DUT 205 connected with the interface device 200 so that the interface libraries 220 can translate requests from the test service 215 and communicate the requests on the appropriate ports of the bridge 240. In any case, once the interface libraries 220 function to initialize the mapping, which may be implemented as list, a table, or another data structure that correlates the ports with the pins, the test service 215 is able to query the interface libraries 220 for information about the DUT 205, as shown at 320, such as an identifier, version number, connected pins/interfaces available with the DUT 205, and so on. It should be appreciated that while a single DUT 205 is described, in further arrangements, the information returned from the interface device 200 may include multiple DUTs. Thus, the interface libraries 220 may then function to provide information about multiple separate DUTs. FIG. 3 further illustrates how the test service 215 proceeds to interact with the DUT 205 via the interface device 200. The illustrated communications generally involve powering the DUT 205, communicating with the DUT 205, and acquiring diagnostic information, such as status reports from the DUT 205 via the connected pins.

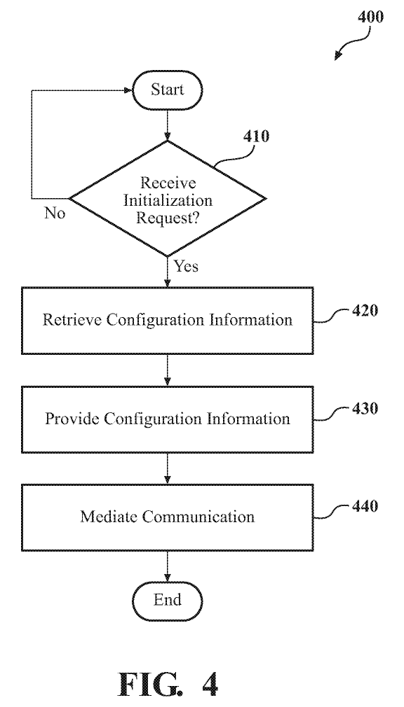

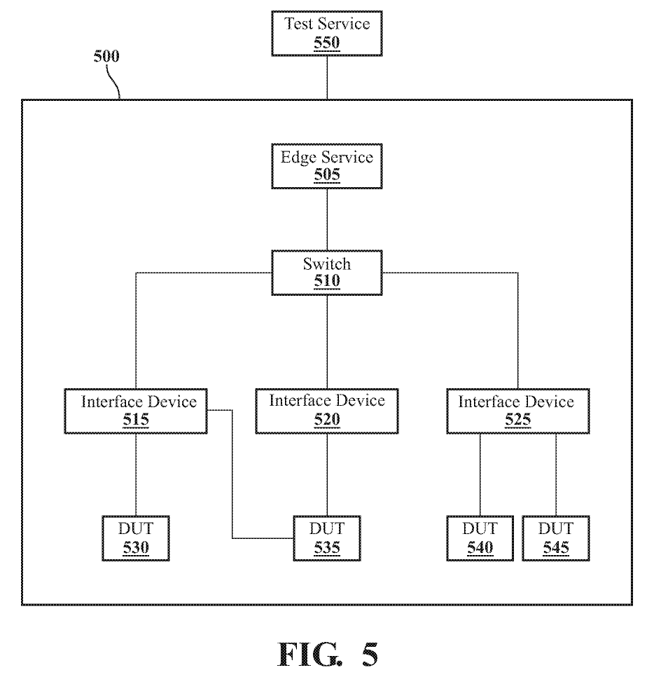

Additional aspects of using an interface device to facilitate communications for testing will be discussed in relation to FIG. 4. FIG. 4 illustrates a flowchart of a method 400 that is associated with adaptably interfacing with a device under test (DUT). Method 400 will be discussed from the perspective of the interface system 100 of FIG. 1 with further reference to the interface device 200 of FIGS. 2A-B. While method 400 is discussed in combination with the noted elements, it should be appreciated that the method 400 is not limited to being implemented within the interface system 100 but is instead one example of a system that may implement the method 400.

At 410, the control module 120 monitors for requests from a device connected with the interface device 200. For example, the interface device 200 may connect directly with another device or may connect with a network on which multiple different devices may communicate. In various arrangements, the interface device 200 connects with the network or directly to the other device via an Ethernet cable or other suitable communication link. In any case, the control module 120, which may be implemented, at least in part, as the management controller 230 monitors for communications and identifies or otherwise distinguishes between different communications. In one approach, the control module 120 monitors for a particular flag in the communication or otherwise parses the communication to determine if the communication is an initialization request to access a test device (i.e., DUT) that is connected with the bridge 240. If the communication is an initialization request, then the control module 120 proceeds to retrieve configuration information, as discussed at 420. Otherwise, the control module 120 continues to monitor the communications.

At 420, the control module 120 retrieves configuration information from a memory within the interface device 200. As previously described, the memory 225 stores configuration information for devices connected to the bridge 240 of the interface device 200. Thus, the memory 225 may store a different selection of configuration information depending on how many devices are connected with the interface device. As such, the control module 120, depending on the implementation, may retrieve the configuration information for all of the attached devices or for device(s) specified in the request. Thus, the control module 120 may parse the request to identify attributes of the request, which generally include the DUTs for which information is being requested. Of course, in alternative arrangements, the control module 120 may simply retrieve information for all DUTs for which configuration information is present in the memory 225.

At 430, the control module 120 provides the configuration information in response to the request. That is, the control module 120 (i.e., the management controller 230) communicates the retrieved configuration information to the requesting device via the transceiver 235. As outlined previously, the configuration information includes at least information that permits the requesting device (e.g., a client instance of the control module 120 executing on the computing device 210) to generate a mapping of pins of the test device for communicating with the test device over the network connection. The mapping then functions to facilitate communication with the test device.

At 440, the control module 120 mediates access to the test device(s). That is, for example, the control module 120 via the management controller 230 and the interface libraries 220 functions to control how the communications are routed to the test device(s). In various arrangements, the control module 120 simply leverages the generated mapping to provide communications to a particular DUT. However, in further arrangements, the control module 120 functions to emulate a wire harness. That is, when multiple separate DUTs are connected with the interface device 200 or with multiple interface devices as discussed further subsequently, the control module 120 can emulate a wire harness by directing the communications as though the test devices are wired in the same manner as if a physical wire harness between the test devices was present.

For example, signals generated by one test device (i.e., DUT 205) can be routed to another test device as though the devices are connected via a physical wire harness. However, the control module 120 instead functions to receive and relay the communications. This permits the control module 120 to emulate any configuration of test devices while further collecting diagnostic/analytics data about how the test devices are functioning. Moreover, the control module 120 can further extend an emulated wire harness among multiple interface devices in order to permit more complex arrangements.

In that regard, consider FIG. 5, which illustrates an edge network 500. The edge network 500 is comprised of an edge service 505, which is generally similar to the computing device 210 of FIG. 2, a switch 510, and multiple interface devices 515, 520, and 525. The interface devices are configured in a similar manner as the interface device 200 of FIG. 2. However, as shown in the edge network 500, the arrangement of DUTs 530, 535, 540, and 545 is distinct from the previous example. In particular, the interface devices 515 and 520 are shown as sharing connections with the DUT 535. This example illustrates how the interface devices 515 and 520 are adaptable to different arrangements. In particular, the interface device 515 may provide for connecting with a portion of the pins of the DUT 535 while the interface device 520 may connect with different pins of the DUT 535. This circumstance may arise in different configurations due to, for example, the DUT 535 including more pins than what can be accommodated by a single interface, to split bandwidth between the separate interface devices 520, as a logical division of functions of the DUT 535 for improved management by the interface devices, and so on.

As one example, the DUT 535 may be a complex module that includes connections with multiple sensors, such as multiple cameras. Moreover, the DUT 535 may further include processing capabilities, management, and other functionality built into multiple different electronic components included therein. As such, the pins associated with the separate functions or in any combination that is desired can be divided between the two interface devices 515 and 520. In this arrangement, the interface devices 515 and 520 separately include configuration information for the pins connected to each individual device and also, in at least one arrangement, general identifying information (e.g., serial number, version number, etc.) for the DUT 535. In this arrangement, the interface device 515 still services the DUT 530 in the same manner as previously described. Accordingly, the ability to split the pins between separate interface devices provides additional flexibility in emulating a wire harness.

The edge network 500 provides for the edge service 505 managing the interface devices 515, 520, and 525. That is, the edge service 505 may function to aggregate information from the interface devices 515-525 in order to simplify access on the part of a test service 550. The test service 550 may be a remote client instance that communicates with the edge service 505 in order to perform automated tests and/or other functions on the DUTs 530-545 either individually or in a particular arrangement (e.g., via an emulated wire harness). Thus, the edge service 505 can be configured to perform various management functions, including implementing the interface libraries 220. In this way, the edge network 500 provides for implementing more complex arrangements of DUTs and also provides access to a wider variety of devices. Moreover, devices within an individual edge network are generally co-located, while separate edge networks may be physically distant and located remotely. In various arrangements, a cloud service, which is described in greater detail subsequently, may schedule jobs (i.e., access to particular DUTs to perform testing) within a single edge network, as opposed to spanning multiple edge networks, when feasible. This may provide for executing multiple copies of a test on separate edge networks in parallel. Of course, in further arrangements, virtual wire harnesses can be implemented, and tests performed in configurations that span multiple edge networks.

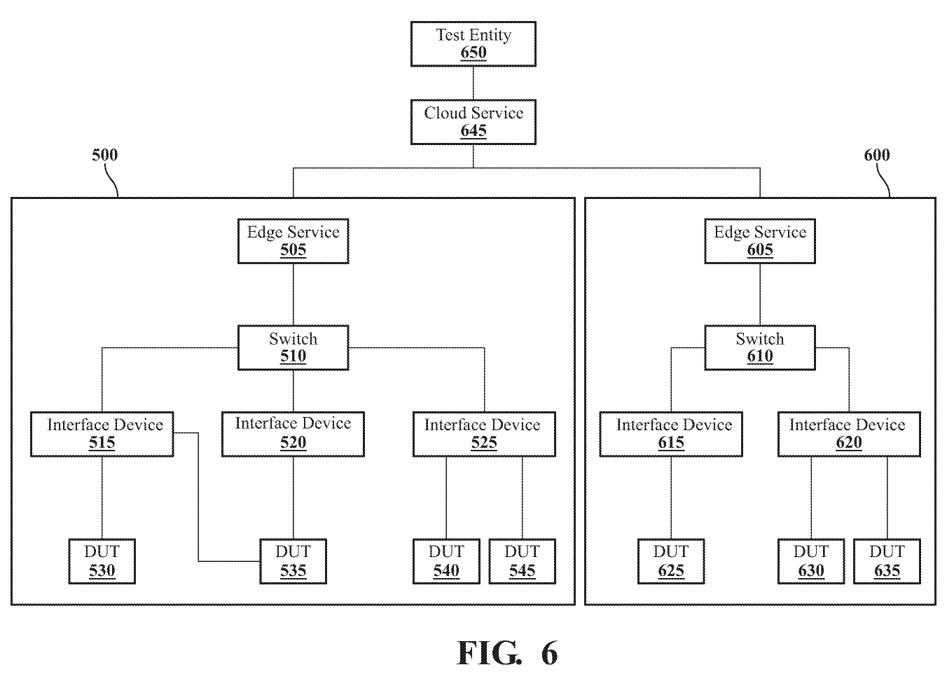

Continuing further with additional implementations of edge services, consider FIG. 6. FIG. 6 illustrates an example implementation of a cloud-based arrangement. As shown in FIG. 6, the edge network 500 functions in parallel with an additional edge network 600. In general, the overall configuration of the edge networks 500 and 600 is similar, except that the number of interface devices and the attached DUTs may vary depending on the particular implementation. For example, the edge network 600 is shown with an edge service 605 and a switch 610, which is similar to the edge network 500. However, the edge network 600 includes two interface devices 615 and 620 with associated DUTs 625, 630, and 640. In further examples, the number of interface devices per edge network may vary to include more or fewer as well as including more or fewer DUTs.

Additionally, a cloud service 645 is shown connected with the edge networks 500/600. The cloud service 645 may provide connections with more or fewer edge networks than shown in the present example. It should be appreciated that the present example is shown for illustrative purposes and should not be construed as limiting the overall structure. In any case, the cloud service 645 further functions to aggregate information about the DUTs within the connected interface devices of the networks 500/600. The cloud service 645 may be a service executing within a cloud-based device (e.g., a computing server) that is connected with a wide area network, the Internet, or another network for providing communications between remote devices. As such, the cloud service 645 functions to provide access to the DUTs via the connected networks and may further provide additional functions. For example, the cloud service 645 may provide reservations for accessing the DUTs, automatic interface, DUT, and emulated harness registration for access by remote clients, statistics/analytics reporting, native interface bridging, and so on.

In further arrangements, the cloud service 645 provides for bridging together the interfaces from the separate networks to emulate a wire harness. Stated otherwise, the cloud service 645 aggregates the information from the separate interface devices dispersed across the separate edge networks (e.g., 500 and 600) and can form a virtual wire harness between selected ones of the available DUTs. The cloud service 645 provides access for a test entity 650 that may include automated tests, developers, and/or other networked entities. In general, the cloud service 645 provides additional layers of functionality on top of the interface devices and the edge services, as previously described.

As one example, the cloud service 645 can provide access for the test entity 650, which may be a testing device executing testing software that supports hardware-in-loop (HILS), software-in-loop (SILS), simulated electronic control units (ECUs) connected via a virtual wire harness, and so on. Thus, the cloud service 645 can provide access to the DUTs 530-545 and 625-635 and/or virtual/emulated wire harnesses, including the DUTs 530-545 and 625-635. As such, the test entity 650, in one or more approaches, uses the cloud service 645 to form more complex virtual wire harnesses that can include emulated entities (e.g., ECUs) and can also provide access for various software routines. In this way, the cloud service 645 provides interface bridging that enables complex test bench setups and multiple interconnected ECUs to be dynamically provisioned without physical vehicle wire harnesses. Thus, instead of implementing a single large test bench with many ECUs connected via physical wiring, each separate ECU can be installed as a DUT in a server rack associated with an interface device and can be dynamically connected via an emulated wire harness to other ECUs, thereby providing for rapid testing across many different wire harnesses or vehicle variants.

Moreover, the cloud service 645 accepts and manages reservations for a set of DUTs (e.g., ECUs). In general, the cloud service 645 queues requests for jobs (e.g., testing) such that usage of the separate DUTs at the different edge networks managed by the cloud service 645 are maximized. Once a reservation is granted, the cloud service 645 manages access for a requesting party to one or more edge services so that the requesting party can connect with interfaces and route traffic to and from the interfaces. The cloud service 645 may implement this service in different forms. For example, in a first approach, the cloud service 645 arranges for an associated edge service to bridge all traffic between the requesting party and the DUT (e.g., ECU) via a GRPC or other remote session protocol. The edge service is then enabled to fully control the connection to prevent malicious actors from accessing the ECU without a reservation. In a separate approach, the cloud service 645 manages the edge service to provide routing services (e.g., as an IP address and port), then the requesting party can directly connect to the ECU with the IP address and port information.

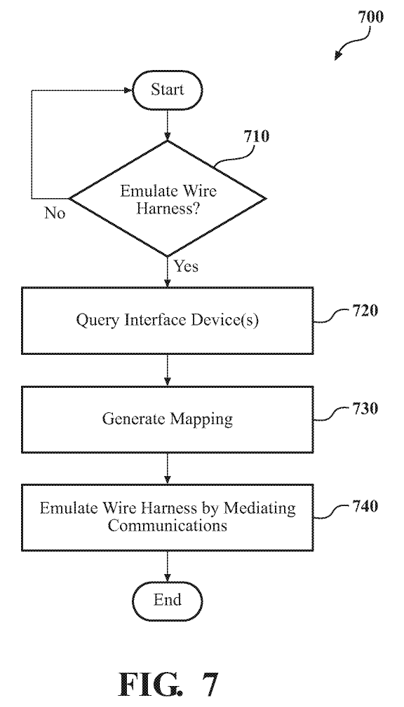

Additional aspects of using an interface device within a cloud services context will be discussed in relation to FIG. 7. FIG. 7 illustrates a flowchart of a method 400 that is associated with emulating a wire harness. Method 700 will be discussed from the perspective of the interface system 100 of FIG. 1 with further reference to the cloud service 645 of FIG. 6. While method 700 is discussed in combination with the noted elements, it should be appreciated that the method 700 is not limited to being implemented within the interface system 100 but is instead one example of a system that may implement the method 700.

At 710, the control module 120 monitors for requests from a device. The device may be the test entity 650, the test service 550, or another computing entity (e.g., a test server) that is attempting to access one or more DUTs. In particular, the request, in at least one arrangement, is in regards to emulating a wire harness. As described herein, emulating a wire harness or, stated otherwise, provisioning a virtual wire harness involves mapping available DUTs connected via interface devices to a network and routing communications therebetween according to virtual associations defined by the emulated wire harness.

Accordingly, the request may indicate a form of the wire harness and different DUTs that are to be connected. As such, the control module 120, which may execute as a client instance as part of the cloud service 645, monitors for the requests via a communication link. Once received, the control module 120 proceeds to perform additional functions in support of emulating the wire harness. Otherwise, the control module 120 proceeds with monitoring at 710.

At 720, the control module 120 queries the interface device(s). In at least one approach, the control module 120 provides queries to each separate interface device to retrieve configuration information for the multiple test devices (i.e., DUTs) that are to be virtually connected via the wire harness. In a further arrangement, the control module 120 instead queries edge services (e.g., 505, 605), which can store aggregated information from the interface devices about available DUTs. In any case, the control module 120 queries the respective entities and aggregates the configuration information in response. As previously noted, the configuration information includes information about the respective DUT (e.g., part number, serial number, etc.) and further includes information about the ports of the bridge to which the pins of the DUT are connected, which provides for facilitating communication with the DUT.

At 730, the control module 120 generates a harness mapping that identifies connections through respective interface devices. In particular, the control module 120 uses the configuration information acquired from the interface devices to define correlations between the DUTs via the port-to-pin correlations. That is, the control module 120, in one arrangement, generates a table, such as a routing table, that indicates which pins should provide signals to other specific pins of different DUTs as would be connected with a physical wire if the harness was physically connected. However, because the harness is being emulated and is virtual, the connections are represented through the harness mapping, which may take the form of a routing table. In this way, the control module 120 is able to emulate any arrangement of devices by simply providing a specific routing configuration between the pins of the devices under test.

At 740, the control module 120 emulates the wire harness. As previously described, the emulation may be performed at the cloud service 645 or the edge service (e.g., 505 or 605). In general, the service that provides the emulation simply permits a different scope of interaction with different interface devices. In particular, the cloud service 645 permits access across multiple edge networks while the edge service is limited to the interface devices connected within the particular network. In any case, the control module 120 can have separate instances executing within the different services to provide for the emulation functionality. Thus, the control module 120 uses the harness mapping to mediate communications between the separate DUTs that are included within a virtual wire harness. In one or more approaches, mediating the communications includes the control module 120 routing signals between the DUTs according to the harness mapping. Thus, the control module 120 identifies the source of the communication (i.e., a particular signal from a particular DUT) and routes the signal to one or more other DUTs according to the harness mapping. In this way, the interface system 100 is able to emulate a wire harness and provide an adaptable test bench environment that overcomes the limitations of physical arrangements.

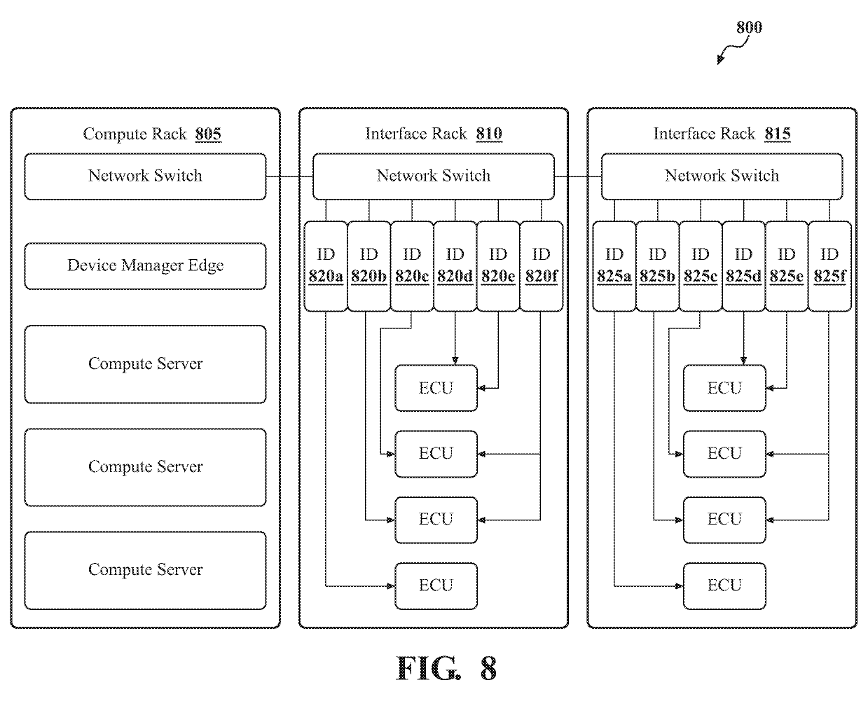

With reference to FIG. 8, one example of a rack system 800 is illustrated as it may be installed within a server. In particular, the rack system 800 is comprised of three primary elements, including a compute rack 805, an interface rack 810, and an interface rack 815. The compute rack 805 includes a network switch to connect with a network to which the other racks 810 are also connected. The compute rack 805 further includes multiple compute servers and a device manager edge. The compute servers may execute various instances of the interface system 100 and/or different test services (e.g., test service 215, test service 550, test entity 650). Thus, the automated test programs and other software that may interact with the interfaces can be executed on the compute rack 805. The interface racks 810 and 815 have similar configurations that include network switches to connect with the network and communicate with the compute rack 805. To the network switches, the interface racks 810 connect multiple interface devices, which are labeled ID 820a-f and 825a-f to associated ECUs that are devices under test. As such, the rack system 800 provides for implementing complex virtual wire harness via edge and cloud services executing on the compute rack 805. In this way, the adaptable interfaces (e.g., 820a-f, 825a-f) improve the testing process by avoiding complexities associated with physical harnesses.

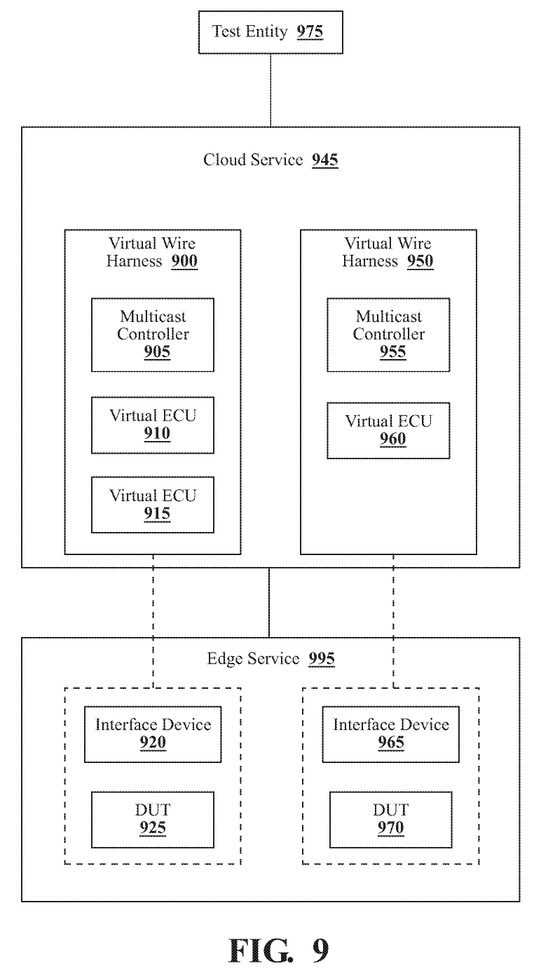

Continuing further with additional implementations of edge services, consider FIG. 9. FIG. 9 illustrates an example implementation of a multicast-based arrangement. As shown in FIG. 9, a virtual wire harness 900 functions in parallel with a virtual wire harness 950. In general, the overall configuration of the virtual wire harness 900 and the virtual wire harness 950 is similar, except that the separation of the two environments is ensured by reliance on a multicast protocol. For example, elements of the virtual wire harness 900 may communicate via a multicast controller 905, while elements of the virtual wire harness 950 may communicate via a multicast controller 955. A multicast controller may be, for example, a controller that receives packets from a set of multicast subscribers and then broadcasts them to the set of multicast subscribers. Further, the controller may also handle communications between multicast subscribers where broadcasting is to be avoided. In some embodiments, a multicast controller may handle multiple sets of multicast subscribers. It is to be understood that the multicast controller described herein is merely exemplary and that other multicast protocols and controllers may be used to implement the methods and systems described herein.

The number of interface devices and the attached DUTs of the virtual wire harnesses may vary depending on a particular implementation, but they are connected within their respective virtual wire harness by assignment to a particular multicast group according to a multicast protocol. For example, the virtual wire harness 900 is shown with a multicast controller 905 that uses a first multicast group assignment to communicate with a virtual ECU 910, a virtual ECU 915, and (through an edge service 995 connected to a cloud service 945) an interface device 920 that provides access to a DUT 925. Similarly, virtual wire harness 950 is shown with a multicast controller 955 that uses a second multicast group assignment to communicate with a virtual ECU 960 and (through the edge service 995 connected to the cloud service 945) an interface device 965 that provides access to a DUT 970.

The cloud service 945 is shown connected with the virtual wire harness 900 and the virtual wire harness 950. The cloud service 945 may be a service as described herein with respect to cloud service 645, but may also include further support for maintaining separation of the virtual wire harness 900 and the virtual wire harness 950 by reliance on multicast group assignments. As such, the cloud service 945 may function to provide access to the DUTs via the connected networks and may further provide additional functions provided that such access complies with multicast group assignments. For example, the cloud service 945 may provide multicast group assignments to edge servers (e.g., edge service 995), DUTs (e.g., DUT 925, DUT 970), interface devices (e.g., interface device 920, interface device 965), and so on. The edge service 995 may be a service as described herein with respect to the edge service 505 or edge service 605, but may also include further support for maintaining separation of the virtual wire harnesses and attached interface devices, DUTs, and so on by reliance on multicast group assignments. Moreover, edge service 995 may include any switches needed (e.g., switch 510, switch 610) to support multicast communications.

Accordingly, the cloud service 945 and edge service 995 provide for bridging together the interfaces from the separate networks via a multicast group assignment to emulate wire harnesses (e.g., the virtual wire harness 900 attached to the DUT 925, the virtual wire harness 950 attached to the DUT 970). Stated otherwise, by relying on a multicast group assignment the cloud service 945 and edge service 995 may enable separate interface devices dispersed across the one or more edge networks to communicate with multiple virtual wire harnesses in a cloud (or to isolate such communications as needed). The cloud service 945 (or edge service 995) also may provide access for a test entity 975 that may include automated tests, developers, and other networked entities. In general, the cloud service 945 and edge service 995 provide additional layers of functionality on top of the interface devices and the edge services, as previously described.

The test entity 975, in one or more approaches, may be a test entity as described herein with respect to the test entity 650, except that the test entity 975 may be aware of some or all of the multicast group assignments within the cloud service 945 (or by extension the edge service 995). In this way, the cloud service 945 provides interface bridging that enables multiple simulation environments that may be adjusted by changing multicast group assignments. Thus, instead of implementing emulated wire harness according to a physical network topology, the cloud service 945 allows for dynamic generation of emulated wire harnesses by changing of multicast group assignments.

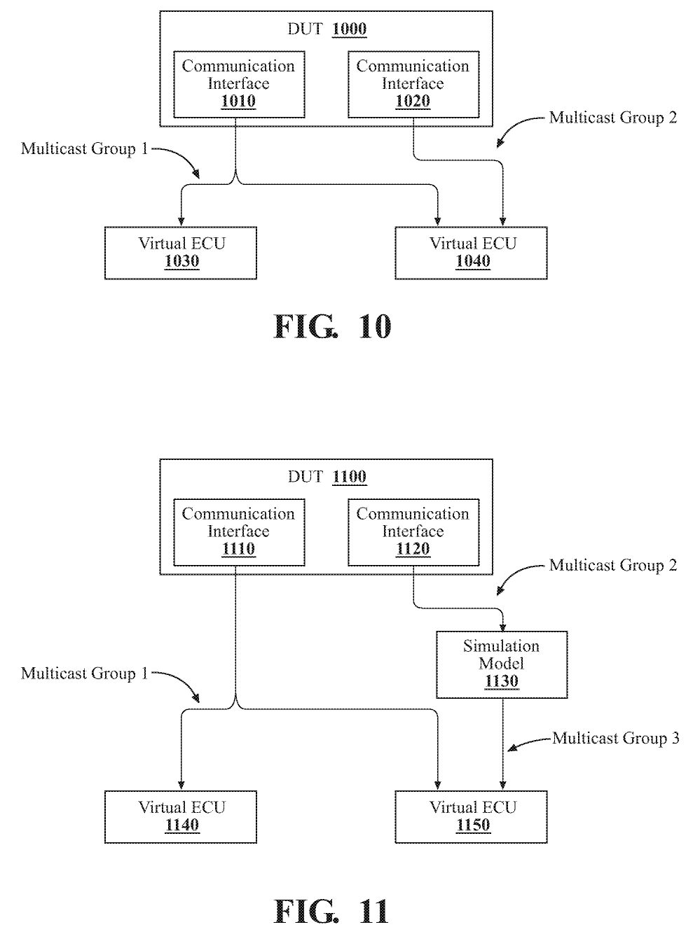

Moreover, the interface device 200 may in some embodiments use multiple multicast group assignments to support emulating one or more wire harnesses. For example, a DUT may have one or more communication interfaces (e.g., CAN bus 0, CAN bus 1, GPIO 3, power input 1) where each communication interface is assigned to communicate using a multicast group assignment by the interface device 200. Accordingly, with respect to FIG. 10, a DUT 1000 may use a communication interface 1010 to communicate with a virtual ECU 1030 and a virtual ECU 1040 (by way of an interface device 200 applying multicast group 1 to communications through communication interface 1010), thereby emulating a first wire harness. Similarly, the DUT 1000 may use a communication interface 1020 to communicate with only the virtual ECU 1040 (by way of the interface device 200 applying multicast group 2 to communications through communication interface 1020), thereby emulating a second wire harness.

In some embodiments, the use of multicast streaming allows for a DUT to be utilized as an input for open-loop testing of multiple virtual wire harnesses, while ensuring isolation between the virtual wire harnesses otherwise. Similarly, multicast group assignments may also be used to provide open-loop testing of multiple DUTs where they share inputs based on a multicast group assignment with the output of a virtual wire harness.

Another example of using multiple multicast group assignments to emulate a wire harness may occur where two or more virtual segments of the virtual wire harness are separated by one or more components (e.g., DUTs, virtual ECUs, simulation models). For example, as shown in FIG. 11, a DUT 1100 may be connected via a communication interface 1110 to a virtual ECU 1140 and a virtual ECU 1150 using multicast group 1. In addition, the DUT 1100 may be connected via a communication interface 1120 to a simulation model 1130 using multicast group 2 and the simulation model 1130 may further connect to the virtual ECU 1150 using multicast group 3. In this manner, multicast may be used to chain together virtual segments or DUTs, thereby preventing intercommunication between the segments except through the desired components (e.g., if simulation model 1130 generates faulty signals, it cannot directly communicate them to virtual ECU 1140).For example, such an arrangement may be desirable where simulation model 1130 is designed to simulate a bad actor that has tapped into a bus.

Where one or more virtual wire harnesses are maintained by cloud service in accordance with multicast group assignments, the test entity 975 may take advantage of the multicast group assignments to facilitate fault injection. For example, the test entity 975 may apply a pre-determined fault function to a virtual wire harness based on the multicast group assignment (e.g., 95% packet loss for a first connection in multicast group 0, 90% packet loss for a second connection in multicast group 1). As another example, by utilizing the multicast group assignment, the test entity 975 may apply a pre-determined fault function (e.g., signal degradation) to a virtual wire harness based on sensor data that indicates noise or temperature levels (e.g., in a place within a vehicle where the virtual wire harness would be installed). In this manner, the use of pre-determined functions in conjunction with the multicast group assignment allows for simulating different levels of packet loss or other faults within one or more virtual wire harnesses.

Furthermore, the interface device 200 may also implement fault injection with respect to multicast group assignments. For example, the interface device 200 may apply a pre-determined fault function to a virtual wire harness based on the multicast group assignment (e.g., multicast group 1 – no communication (unplugged), multicast group 2 – pins 7-10 no communication (ribbon cut)). As another example, by utilizing the multicast group assignment, the interface device 200 may apply a pre-determined fault function (e.g., signal degradation, resistor failure) to a DUT connection using different connection types (e.g., 0.3m unshielded twisted pair, 0.4m shielded twisted pair, .25m coaxial). In this manner, the use of pre-determined functions in conjunction with the multicast group assignment allows for simulating different levels of packet loss or other faults within one or more DUT connections to one or more virtual wire harnesses.

In some embodiments, if the interface device 200 receives a packet via multicast group 0 for a DUT, it may use different configuration information for the DUT than if it had received the packet via multicast group 1. This approach may occur where components of multicast group 0 involved in testing signals on the DUT have no impact on testing involving components of multicast group 1, such as where independent subfunctions of the DUT are being analyzed. However the interface device 200 may nonetheless need to implement an appropriate mapping depending on the multicast group assignment. In some embodiments, the interface device 200 may incorporate multicast group assignments within the configuration information for a DUT (e.g., data associated with a first partial mapping of a DUT may be provided in accordance with a first multicast group assignment, while data associated with a second partial mapping of the DUT may be provided in accordance with a second multicast group assignment). In some embodiments, where the simultaneous use of the DUT is not possible through multicast, the interface device 200 may indicate to the cloud service 945, the edge service 995, the test entity 975, or a combination thereof which multicast group assignment the interface device 200 is configured for (e.g., multicast group 1), when the interface device 200 is switching support for multicast group assignments (e.g., swapping configuration information), or the time at which the interface device 200 will be available to support a different multicast group assignment (e.g., according to scheduled availability).

In some embodiments, multicast group assignments may be used to enhance the reliability of the cloud service 945, the edge service 995, or both. For example, it may be acceptable within a testing environment to utilize prototype devices prone to a high rate of failure so long as such failure can be detected and addressed without affecting testing results. One such instance may involve prototypes where it is necessary to perform testing with prototypes that have not yet achieved a desired level of reliability. Rather than hold up the development of other components, the cloud service 945 and the edge service 995 may utilize multicasting to stream the output of an emulated wire harness as inputs to an array of prototype DUTs whose outputs are monitored for non-compliance. If a DUT is determined to be non-compliant, it can be removed from the array and a replacement DUT added. For example, a simple test for non-compliance is whether, in response to the streaming input from the emulated wire harness, a DUT’s performance degrades relative to two other DUT’s within the array. When such degradation is detected, a replacement DUT may be substituted for the degraded DUT (e.g., by changing multicast group assignments, manually swapping out the degraded DUT).

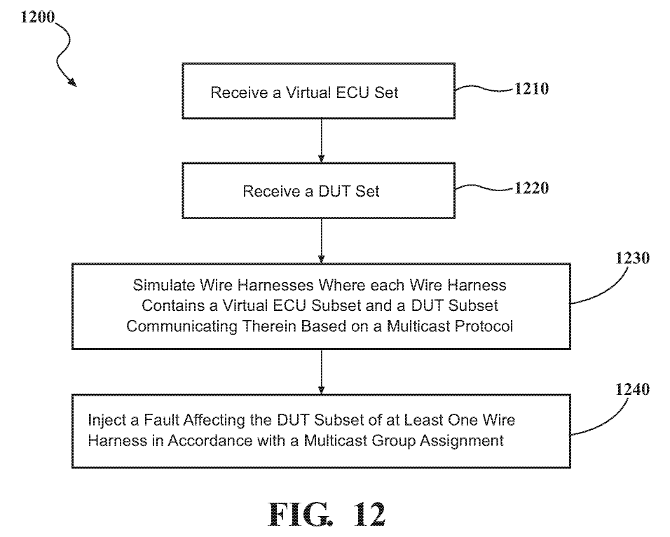

Additional aspects of using an interface device within a multicast-based context will be discussed in relation to FIG. 12. FIG. 12 illustrates a flowchart of a method 1200 that is associated with emulating one or more wire harnesses. Method 1200 will be discussed from the perspective of the interface system 100 of FIG. 1 with further reference to the cloud service 945 and the edge service 995 of FIG. 9. While method 1200 is discussed in combination with the noted elements, it should be appreciated that the method 1200 is not limited to being implemented within the interface system 100 but is instead one example of a system that may implement the method 1200.

At 1210, the cloud service 945 may receive a virtual ECU set. For example, the cloud service 945 may select a set of virtual electronic control units available to the cloud service 945 in order to emulate a wire harnesses.

At 1220, the cloud service 945 may receive a DUT set. For example, the cloud service 945 may select a set of interface devices, which are connected to DUTs, available to the cloud service 945 through the edge service 995 in order to emulate wire harnesses.

At 1230, the cloud service 945 may simulate wire harnesses where each wire harness contains a virtual ECU subset and a DUT subset communicating therein based on a multicast protocol. For example, each wire harness may be assigned a unique multicast group assignment by which the virtual ECU subset and DUT subset communicate.

At 1240, the cloud service 945 may inject a fault affecting the DUT subset of at least one wire harness in accordance with a multicast group assignment. For example, a fault may be specified by a test entity, such that the cloud service 945 applies the fault to a particular wire harness in accordance with the multicast group assignment associated with the particular wire harness.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-12, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. The systems, components and/or processes also can be embedded in a computer-readable storage, such as a computer program product or other data program storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. The phrase “computer-readable storage medium” means a non-transitory storage medium. A computer-readable storage medium may be, for example, an electronic, magnetic, optical, electromagnetic, infrared, or semiconductor system, apparatus, or device, or any suitable combination of the foregoing. A non-exhaustive list of the computer-readable storage medium can include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or a combination of the foregoing. In the context of this document, a computer-readable storage medium is, for example, a tangible medium that stores a program for use by or in connection with an instruction execution system or device.

Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through a network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of … and ….” as used herein refers to and encompasses any and all possible combinations of one or more of the associated listed items. As an example, the phrase “at least one of A, B, and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. An interface system, comprising:
one or more processors; and
a memory communicably coupled to the one or more processors and storing a control module, including instructions that, when executed by the one or more processors, cause the one or more processors to:
receive a set of virtual electronic control units;
receive a set of interface devices connected to test devices;
simulate wire harnesses where each wire harness contains a subset of virtual electronic control units and a subset of interface devices, both of which are configured to communicate therein based on a multicast protocol; and
inject a fault in a target wire harness affecting a test device connected to the subset of interface devices associated with the target wire harness in accordance with a multicast group assignment.

2. The interface system of claim 1, wherein the instruction to simulate the wire harnesses includes at least one wire harness where being configured to communicate therein based on the multicast protocol incorporates multiple multicast group assignments.

3. The interface system of claim 2, wherein the at least one wire harness incorporates multiple multicast group assignments into configuration information corresponding to at least one test device.

4. The interface system of claim 1, wherein the instructions to simulate the wire harnesses include at least two wire harnesses being configured to communicate with a shared interface device using a shared multicast group assignment.

5. The interface system of claim 1, wherein the instructions to simulate the wire harnesses includes at least two wire harnesses being configured to communicate with a shared interface device using different multicast group assignments.

6. The interface system of claim 1, wherein the instruction to inject the fault includes to apply a pre-determined function whose output is based on the multicast group assignment.

7. The interface system of claim 1, wherein the instructions further include to swap a failed test device with a replacement test device by changing multicast group assignments.

8. A non-transitory computer-readable medium including instructions that, when executed by one or more processors, cause the one or more processors to:
receive a set of virtual electronic control units;
receive a set of interface devices connected to test devices;
simulate wire harnesses where each wire harness contains a subset of virtual electronic control units and a subset of interface devices, both of which are configured to communicate therein based on a multicast protocol; and
inject a fault in a target wire harness affecting a test device connected to the subset of interface devices associated with the target wire harness in accordance with a multicast group assignment.

9. The non-transitory computer-readable medium of claim 8, wherein the instruction to simulate the wire harnesses includes at least one wire harness where being configured to communicate therein based on the multicast protocol incorporates multiple multicast group assignments.

10. The non-transitory computer-readable medium of claim 9, wherein the at least one wire harness incorporates multiple multicast group assignments into configuration information corresponding to at least one test device.

11. The non-transitory computer-readable medium of claim 8, wherein the instruction to simulate the wire harnesses includes at least two wire harnesses being configured to communicate with a shared interface device using a shared multicast group assignment.

12. The non-transitory computer-readable medium of claim 8, wherein the instruction to simulate the wire harnesses includes at least two wire harnesses being configured to communicate with a shared interface device using different multicast group assignments.

13. The non-transitory computer-readable medium of claim 8, wherein the instruction to inject the fault includes to apply a pre-determined function whose output is based on the multicast group assignment.

14. A method, comprising:
receiving a set of virtual electronic control units;
receiving a set of interface devices connected to test devices;
simulating wire harnesses where each wire harness contains a subset of virtual electronic control units and a subset of interface devices, both of which are configured to communicate therein based on a multicast protocol; and
injecting a fault in a target wire harness affecting a test device connected to the subset of interface devices associated with the target wire harness in accordance with a multicast group assignment.

15. The method of claim 14, wherein simulating the wire harnesses includes at least one wire harness where being configured to communicate therein based on the multicast protocol incorporates multiple multicast group assignments.

16. The method of claim 15, wherein the at least one wire harness incorporates multiple multicast group assignments into configuration information corresponding to at least one test device.

17. The method of claim 16, wherein simulating the wire harnesses includes at least two wire harnesses being configured to communicate with a shared interface device using a shared multicast group assignment.

18. The method of claim 14, wherein simulating the wire harnesses includes at least two wire harnesses being configured to communicate with a shared interface device using different multicast group assignments.

19. The method of claim 14, wherein injecting the fault includes to apply a pre-determined function whose output is based on the multicast group assignment.

20. The method of claim 14, further comprising swapping a failed test device with a replacement test device by changing multicast group assignments.
